(19) United States
(12) Patent Application Publication
(10) Pub. No.: US 2013/0234772 A1
(43) Pub. Date: Sep. 12, 2013

(54) CLOCK SUPPLY CIRCUIT

(71) Applicant: NIHON KOHDEN CORPORATION, Tokyo (JP)

(72) Inventor: Tetsuo SUZUKI, Tokyo (JP)

(73) Assignee: NIHON KOHDEN CORPORATION, Tokyo (JP)

(21) Appl. No.: 13/735,567

(22) Filed: Jan. 7, 2013

(30) Foreign Application Priority Data
Mar. 6, 2012 (JP) 2012-049050

(51) Int. Cl. H03K 3/00

(52) U.S. Cl. CPC H03K 3/00
USPC 327/299

(57) ABSTRACT

A circuit that supplies a clock signal to a load having a clock input section capable of suppressing power consumption is disclosed. A clock generating section generates a clock signal having an amplitude corresponding to an absolute value of an electric potential difference between a lower limit of a high-level input voltage V_{IH} and an upper limit of a low-level input voltage V_{IL} in a load having a clock input section; a level shift section shifts an electric potential while maintaining the amplitude of the clock signal so that a high-level electric potential of the clock signal is not less than the lower limit of the high-level input voltage V_{IH} and a low-level electric potential of the clock signal does not exceed the upper limit of the low-level input voltage V_{IL}, and a clock signal whose electric potential is shifted is supplied to the clock input section.

### BACKGROUND OF THE INVENTION

The present invention relates to a circuit that supplies a clock signal to a load having a clock input section, such as a CPU.

As this kind of circuit, a circuit is known that supplies a clock signal, whose voltage value changes between 0 V and 3.3 V, to a load, which operates when the high-level input voltage of an input clock signal (rectangular wave) is equal to or higher than 2.0 V and the low-level input voltage is equal to or lower than 0.8 V. In addition, the value of 3.3 V is known as a universal voltage that a CPU serving as a load usually requires.

A clock input section of the load has an input capacitor (a floating capacitor or the like), and this is charged and discharged by the clock signal. As the amplitude (electric potential difference between the maximum voltage value and the minimum voltage value) of the clock signal increases, power consumption increases.

It is possible to consider measures for reducing power consumption while ensuring a reliable operation by generating a clock signal with a small amplitude whose voltage value changes between 0.5 V and 2.3 V, which is a range when the margin of ±0.3 V is added to the low-level input voltage 0.8 V and the high-level input voltage 2.0 V of the clock signal. However, in order to obtain the voltage values of 0.5 V and 2.3 V, it is necessary to prepare a separate power supply circuit. As a result, the circuit configuration becomes complicated and the cost increases. In addition, electric power is consumed by the power supply circuit itself.

On the other hand, a circuit that generates, for example, a universal clock signal with a small amplitude, and supplies the universal clock signal, after converting this into a clock signal with a large amplitude corresponding to the operating voltage of a predetermined load, using a level converter circuit, is known (for example, Patent Documents 1 and 2).

### RELATED ART REFERENCE

### Patent Reference

(Patent Reference 1) Japanese Patent No. 4707858
(Patent Reference 2) Japanese Patent No. 3473745

Incidentally, 1.8 V is known as a universal voltage that a CPU usually requires. Therefore, it may be considered to generate a universal clock signal with a small amplitude whose voltage value changes between 0 V and 1.8 V, convert the universal clock signal into a clock signal with a large amplitude whose voltage value changes between 0 V and 2.3 V by applying the level converter circuit disclosed in Patent Documents 1 and 2, and supply the converted signal to the above-described load. According to this, power consumption due to the charge and discharge of the input capacitor of the load can be suppressed to some extent. However, since the margin on the low-level input voltage side is too large, unnecessary electric power is consumed. In addition, since the level converter circuit itself also has an input capacitor, electric power to operate the level converter circuit itself cannot be neglected either. Accordingly, since separate power consumption occurs, a sufficient power saving effect is not obtained as a whole.

### SUMMARY

This invention provides a clock supply circuit capable of obtaining a sufficient power saving effect.

It is therefore an aspect of the invention to provide a clock supply circuit including:

a clock generating section configured to generate a clock signal having an amplitude corresponding to an absolute value of an electric potential difference between a lower limit of a high-level input voltage and an upper limit of a low-level input voltage in a load having a clock input section; and

a level shift section configured to shift an electric potential while maintaining the amplitude of the clock signal generated by the clock generating section so that a high-level electric potential of the clock signal is not less than the lower limit of the high-level input voltage and a low-level electric potential of the clock signal does not exceed the upper limit of the low-level input voltage,

wherein the level shift section includes a capacitor connected in series between the clock generating section and the clock input section and a first resistor inserted between a positive side of a voltage source and a downstream end of the capacitor, and

a clock signal whose electric potential has been shifted by the level shift section is supplied to the clock input section.

According to such a configuration, a clock signal with which a load can operate and whose amplitude is small can be supplied to a clock input section. Although the input capacitor of the clock input section is charged and discharged by the clock signal, it is possible to reduce power consumption according to charge and discharge since the amplitude of the clock signal is small.

In addition, in the level shift section configured by the capacitor and the first resistor, power consumption can be neglected in practice. For this reason, additional power consumption due to providing the level shift section between the clock generating section and the clock input section mostly does not occur. Accordingly, power consumption of the entire circuit can also be suppressed.

In addition, realizing the level shift section with the very simple circuit configuration using the capacitor and the first resistor contributes to the miniaturization of the clock supply circuit and cost reduction.

The level shift section may further include a second resistor inserted between the downstream end of the capacitor and a negative side of the voltage source.

In this case, the electric potential shifted by the level shift section can be determined as a divided voltage value of the universal voltage source by appropriately setting the values of the first and second resistors.

In addition, since a high pass filter is formed by a capacitor and a resistor in all configurations, it is possible to remove low-frequency noise included in the clock signal.

When the amplitude of the clock signal is a value corresponding to the universal voltage of the load, it is not necessary to provide a new constant voltage source. Accordingly, it is possible to suppress both the cost and consumed power.

### BRIEF DESCRIPTION OF THE DRAWINGS

FIG. 1 is a functional block diagram showing the configuration of a clock supply circuit according to an embodiment of the invention.

FIG. 2 is a circuit diagram showing the configuration of a level shift section in the clock supply circuit shown in FIG. 1.

FIG. 3 is a circuit diagram showing a modification of the level shift section shown in FIG. 2.

### DETAILED DESCRIPTION OF EMBODIMENTS

An embodiment of the invention will be described in detail below while referring to the accompanying drawings.

FIG. 1 is a functional block diagram showing the configuration of a clock supply circuit 10 according to an embodiment of the invention. The clock supply circuit 10 is electrically connected to a CPU 20 as a load. The clock supply circuit 10 includes a clock generating section 11 and a level shift section 12.

The CPU 20 is configured to operate with a clock signal supplied to a clock input section 21. In the present embodiment, the high-level input voltage V_{IH} of a clock signal in the CPU 20 is equal to or higher than 2.0 V and the low-level input voltage V_{IL} is equal to or lower than 0.8 V.

The clock generating section 11 is configured to generate a clock signal 13 having an amplitude corresponding to the absolute value of the electric potential difference between the lower limit of the high-level input voltage V_{IH} and the upper limit of the low-level input voltage V_{IL} in the CPU 20. Specifically, in order to guarantee the reliability of the operation for variations in characteristics among products of the CPU 20, an appropriate margin is added so as not to be less than the absolute value. In addition, in order to suppress the power consumed by the clock signal 13 as much as possible, the value of the amplitude is set such that the margin becomes as small as possible.

In the present embodiment, the clock generating section 11 is configured to generate the rectangular-wave clock signal 13 having an amplitude of the electric potential difference (that is, 1.8 V) when the margin (±0.3 V) is added to the absolute value (1.2 V) of the electric potential difference between the lower limit (2.0 V) of the high-level input voltage V_{IH} and the upper limit (0.8 V) of the low-level input voltage V_{IL} in the CPU 20. Therefore, the clock generating section 11 is configured as a circuit that generates the clock signal 13 whose voltage value changes between 0 V and 1.8 V.

Since the voltage value of 1.8 V is a voltage (universal voltage) that the CPU 20 originally requires, it is not necessary to provide a new constant voltage source. Accordingly, it is possible to suppress both the cost and consumed power.

The level shift section 12 is configured to increase the electric potential (shift the level) while maintaining the amplitude of the clock signal 13 so that the high-level electric potential of the clock signal 13 generated by the clock generating section 11 is not less than the lower limit of the high-level input voltage V_{IH} and the low-level electric potential of the clock signal does not exceed the upper limit of the low-level input voltage V_{IL}. Specifically, the level shift section 12 outputs a level-shifted clock signal 14 whose voltage value changes between 0.5 V and 2.3 V while maintaining the amplitude of 1.8 V.

The level shift section 12 is electrically connected to the clock input section 21 of the CPU 20, and supplies the level-shifted clock signal 14 to the clock input section 21. The CPU 20 performs a predetermined operation according to the level-shifted clock signal 14.

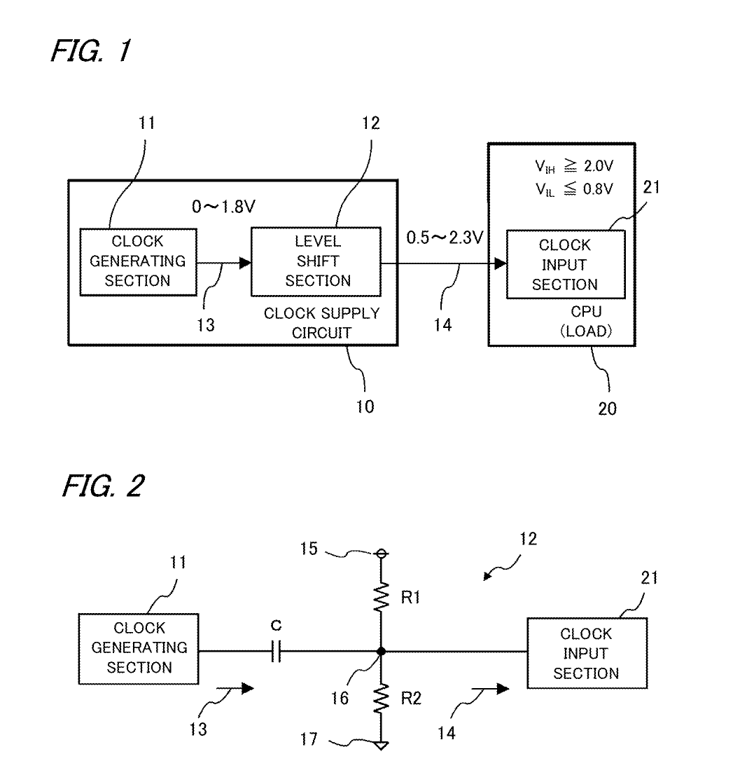

As shown in FIG. 2, the level shift section includes a capacitor C and first and second resistors R1 and R2. The capacitor C is connected in series between the clock generating section 11 the clock input section 21. The first resistor R1 is inserted between a positive side 15 of a universal voltage source and a downstream end 16 of the capacitor C. The second resistor R2 is inserted between the downstream end 16 of the capacitor C and a negative side (ground) 17 of the universal voltage source.

Since the capacitor C and the first and second resistors R1 and R2 form a high pass filter as a result, low-frequency noise included in the clock signal 13 is removed. In addition, in order to reduce the distortion of the waveform of the clock signal 14 that is level-shifted so as to be recognized by the CPU 20, the values of the capacitor C and the first and second resistors R1 and R2 are set so that the cut-off frequency of the high pass filter becomes as low as possible. Specifically, the cut-off frequency of the high pass filter is set to at least 1/10 or less of the frequency of the clock signal 13.

The resistance value of each of the first and second resistors R1 and R2 is appropriately set such that the divided voltage value of the power supply voltage, which is supplied from the positive side 15 of the universal voltage source, at the downstream end 16 of the capacitor C becomes a center potential of the amplitude of the level-shifted clock signal 14. In the present embodiment, the electric potential at the downstream end 16 is set to 1.4 V which is a center potential between 0.5 V and 2.3 V. In order to suppress power consumption, it is preferable that each resistance value be high. However, a resistor having a resistance value of several hundred kΩ is used in consideration of noise and the like.

According to such a configuration, a clock signal with which the CPU 20 can operate and whose amplitude is small can be supplied to the clock input section 21. Since the input capacitor of the clock input section 21 is charged and discharged by the clock signal, electric power corresponding to the amplitude of the clock signal consumed. However, due to the clock signal whose amplitude has been reduced, it is possible to reduce power consumption to be as small as possible.

In addition, in the level shift section 12 configured by the capacitor C, the first resistor R1, and the second resistor R2, the resistance values of the first and second resistors R1 and R2 are set to several hundred kΩ as described above. Accordingly, since the electric power is in the order of μW, power consumption is very low. For this reason, additional power consumption due to providing the level shift section 12 between the clock generating section 11 and the clock input section 21 can be neglected in practice. As a result, power consumption of the entire circuit can also be suppressed.

In addition, realizing the level shift section 12 with the very simple circuit configuration using the capacitor C and the first and second resistors R1 and R2 contributes to the miniaturization of the clock supply circuit and cost reduction.

The embodiment described above is intended to facilitate understanding of the invention, and does not limit the invention. The invention may be changed or modified without departing from the spirit, and it is needless to say that the equivalents are included in the invention.

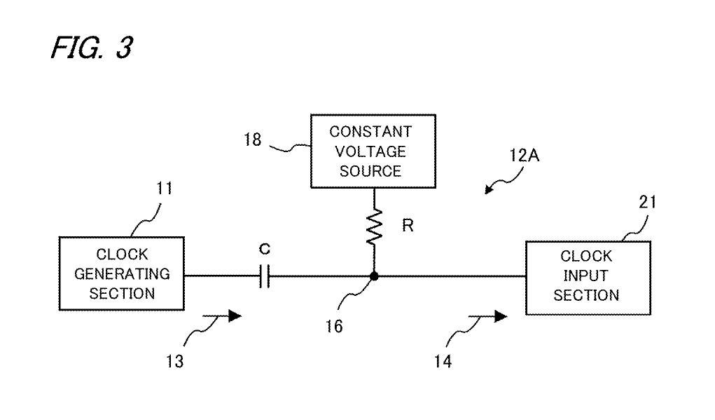

The circuit configuration of the level shift section is not limited to that shown in the above-described embodiment. For example, as a level shift section 12A shown in FIG. 3, a dedicated constant voltage source 18 may be used as a voltage source. In this case, a resistor R as the first resistor of the invention is inserted between the constant voltage source 18 and the downstream end 16 of the capacitor C. The resistance value of the resistor R is appropriately set such that the electric potential of the downstream end 16 of the capacitor C becomes a center potential (in the present embodiment, 1.4 V) of the amplitude of the level-shifted clock signal 14.

The amplitude of the clock signal 13 generated by the clock generating section 11 is preferably close to the absolute value of the electric potential difference between the lower limit of the high-level input voltage V_{IH} and the upper limit of the low-level input voltage V_{IL} in the CPU 20 (load). In the configuration shown in FIG. 2, the electric potential difference is set to 1.8 V using the existing universal voltage source. Accordingly, a sufficient margin set. On the other hand, if the dedicated voltage source 18 is provided as shown in FIG. 3, it is possible to reduce the margin in order to reduce power consumption of the entire circuit.

The load to which the clock supply circuit according to the invention can be connected is not limited to the CPU 20. The clock supply circuit according to the invention may be applied to an appropriate load as long as the load can operate in response to the input of a high-frequency clock signal. For example, a driving element of a liquid crystal display may be included.

According to the configuration of the invention, it is possible to suppress power consumption in a circuit that supplies a clock signal to a load having a clock input section.

What is claimed is:

1. A clock supply circuit comprising:
a clock generating section configured to generate a clock signal having an amplitude corresponding to an absolute value of an electric potential difference between a lower limit of a high-level input voltage and an upper limit of a low-level input voltage in a load having a clock input section; and
a level shift section configured to shift an electric potential while maintaining the amplitude of the clock signal generated by the clock generating section so that a high-level electric potential of the clock signal is not less than the lower limit of the high-level input voltage and a low-level electric potential of the clock signal does not exceed the upper limit of the low-level input voltage,
wherein the level shift section includes a capacitor connected in series between the clock generating section and the clock input section and a first resistor inserted between a positive side of a voltage source and a downstream end of the capacitor, and
a clock signal whose electric potential has been shifted by the level shift section is supplied to the clock input section.

2. The clock supply circuit according to claim 1,
wherein the level shift section further includes a second resistor inserted between the downstream end of the capacitor and a negative side of the voltage source.

3. The clock supply circuit according to claim 1,
wherein the amplitude of the clock signal is a value corresponding to a universal voltage of the load.

4. The clock supply circuit according to claim 2,
wherein the amplitude of the clock signal is a value corresponding to a universal voltage of the load.
